(19) United States
(12) Patent Application Publication
(10) Pub. No.: US 2026/0314456 A1
(43) Pub. Date: Oct. 8, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Yong Ho SON, Seoul (KR); Moo Seong KIM, Seoul (KR); Jung Eun HAN, Seoul (KR)

(73) Assignee: LG INNOTEK CO., LTD., Seoul (KR)

(21) Appl. No.: 19/484,216

(22) PCT Filed: Jun. 10, 2024
(86) PCT No.: PCT/KR2024/007854

§ 371 Date: Nov. 13, 2025

(30) Foreign Application Priority Data
Jun. 15, 2023 (KR) 10-2023-0076881

(51) Int. Cl. H10W 70/685; H10W 42/20; H10W 70/63

(52) U.S. Cl. CPC H10W 70/685; H10W 42/20; H10W 70/63

(57) ABSTRACT

Disclosed in an embodiment of the present invention is a circuit board comprising: a first insulating layer; a first circuit pattern layer disposed on the first insulating layer; a second insulating layer disposed on the first insulating layer and the first circuit pattern layer, and including a cavity; a second circuit pattern layer disposed on the second insulating layer; and a connection layer passing through the second insulating layer and disposed along the edge of the cavity.

### TECHNICAL FIELD

Embodiments of the present invention relate to a circuit board and a semiconductor package.

### BACKGROUND ART

As high performance of electrical/electronic products proceeds, techniques for attaching a larger number of packages to a substrate of a limited size have been proposed and studied. However, since a general package is based on a single semiconductor chip being mounted, there is a limitation in obtaining desired performance.

A general circuit board or package substrate has a form in which a processor package in which a processor chip is disposed and a memory package to which a memory chip is attached are connected to each other. This package substrate has the advantage of reducing a mounting area of the chip and enabling high-speed signal transmission through a short path by manufacturing a processor chip and a memory chip as a single integrated package. Due to this advantage, the package substrate is widely used in mobile devices, etc.

Meanwhile, a size of a package is increasing due to the recent advancements in electronic devices such as mobile devices and adoption of a high bandwidth memory (HBM). In addition, as functions required in an application processor increase, there is a need to configure each function as a separate processor chip and to have a circuit substrate on which processor chips can be mounted. In this time, for the application processor, even when it is separated into two processor chips by function, the number of terminals (input/output) provided in each processor chip is increasing.

In addition, due to recent developments such as 5G, the Internet of Things (IoT), increased image quality, and increased communication speed, the number of terminals of a processor chip is gradually increasing as the number of power and signals increases. Accordingly, the area and thickness of a circuit board and a circuit pattern density are also increasing. When the area and thickness of the circuit board increase, it becomes difficult to miniaturize a product, and there are problems such as reliability issues such as warpage of the circuit board and an increased product price. Therefore, increasing the density of the circuit pattern is more advantageous in terms of a product price, reliability such as warpage and miniaturization of the product, than increasing the area and thickness of the circuit board. Thus, fineness of the circuit pattern or through electrode is required.

In addition, at least one processor chip is mounted on a circuit board or package substrate and high integration is achieved, and in this situation, the need for electromagnetic shielding for the processor chip is also increasing.

### DISCLOSURE

### Technical Problem

Embodiments of the present invention provides a circuit board in which an input/output count of the circuit board is improved through cavities disposed in some insulating layers, and a semiconductor package including the same.

In addition, the embodiments may provide a circuit board that provides electromagnetic wave shielding by arranging a connection layer adjacent to a cavity and electrically connecting the connection layer to an upper shield layer, and a semiconductor package including the same.

In addition, the embodiments may provide a circuit board in which prevents an issue of non-formation of a side surface of a shield layer and reduction in manufacturing speed for forming the side surface of the shield layer by performing connection to the shield layer disposed on an upper portion through a connection layer on a side surface of the cavity, and a semiconductor package including the same.

In addition, the embodiments may provide a circuit board in which warpage of the circuit board is prevented through a connection layer, and a semiconductor package including the same.

Problems to be solved in the embodiments are not limited to the above-described problems, and objectives and effects which can be determined from the solutions and the embodiments of the problems described below are also included.

### Technical Solution

A circuit board according to embodiments of the present invention includes a first insulating layer, a first circuit pattern layer disposed in the first insulating layer, a second insulating layer disposed on the first insulating layer and the first circuit pattern layer and including a cavity, a second circuit pattern layer disposed in the second insulating layer, and a connection layer passing through the second insulating layer and disposed along an edge of the cavity.

The connection layer may overlap the second circuit pattern layer at an outer side of the cavity in a direction perpendicular to a stack direction.

The connection layer may be disposed between the second circuit pattern layer and the cavity or disposed at an outer side of the second circuit pattern layer.

The connection layer may be electrically connected to the first circuit pattern layer.

The connection layer may be electrically connected to the second circuit pattern layer.

The connection layer may surround the cavity in the form of an open loop or a closed loop.

The connection layer may include a plurality of first sub-connection layers and a plurality of second sub-connection layers which are adjacent to each other, and the first sub-connection layer and the second sub-connection layer are disposed and spaced apart from each other.

The circuit board may further include a first extension extending in a direction perpendicular to a stack direction and configured to connect the connection layer to the second circuit pattern layer.

The first extension may be disposed in the second insulating layer.

The circuit board may further include a second extension extending in a stack direction and configured to connect the connection layer to the first circuit pattern layer.

The second extension may be disposed in the first insulating layer.

The cavity may include a first cavity and a second cavity spaced apart from the first cavity.

The connection layer may include a first connection layer surrounding the first cavity and a second connection layer surrounding the second cavity.

The first connection layer and the second connection layer may be in contact with or spaced apart from each other.

A package substrate according to embodiments of the present invention includes a circuit board, a semiconductor element connected to the circuit board, and a connection part configured to connect the semiconductor element to the circuit board, wherein the circuit board includes a first insulating layer, a first circuit pattern layer disposed in the first insulating layer, a second insulating layer disposed on the first insulating layer and the first circuit pattern layer and including a cavity, a second circuit pattern layer disposed in the second insulating layer, and a connection layer passing through the second insulating layer and disposed along an edge of the cavity, the package substrate further includes a shield layer disposed at an outer side of the second insulating layer, and the connection layer is electrically connected to the shield layer.

### Advantageous Effects

Embodiments of the present invention can implement a circuit board in which an input/output count of the circuit board is improved through cavities disposed in some insulating layers, and a semiconductor package including the same.

In addition, the embodiments can implement a circuit board that provides electromagnetic wave shielding by arranging a connection layer adjacent to a cavity and electrically connecting the connection layer to an upper shield layer, and a semiconductor package including the same.

In addition, the embodiments can implement a circuit board in which prevents an issue of non-formation of a side surface of a shield layer and reduction in manufacturing speed for forming the side surface of the shield layer by performing connection to the shield layer disposed on an upper portion through a connection layer on a side surface of the cavity, and a semiconductor package including the same.

In addition, the embodiments can implement a circuit board in which warpage of the circuit board is prevented through a connection layer, and a semiconductor package including the same.

Various beneficial advantages and effects of the present invention are not limited by the detailed description and should be easily understood through a description of a detailed embodiment of the present invention.

### DESCRIPTION OF DRAWINGS

FIG. 1 is a conceptual diagram illustrating a circuit board according to an embodiment of the present invention.

FIG. 2 is a diagram illustrating a circuit board according to a first embodiment.

FIG. 3 is an enlarged diagram illustrating a portion of FIG. 2.

FIG. 4 is a diagram illustrating a modified example of FIG. 3.

FIG. 5 is a plan view of the circuit board according to the first embodiment.

FIG. 6 is a diagram along line AA′ in FIG. 5.

FIG. 7 is a diagram along line BB′ in FIG. 5.

FIGS. 8 and 9 are flowcharts illustrating a method of manufacturing a circuit board according to the first embodiment.

FIG. 10 is a plan view of the circuit board according to a second embodiment.

FIG. 11 is a diagram along line CC′ in FIG. 10.

FIG. 12 is a diagram along line DD′ in FIG. 10.

FIG. 13 is a diagram along line EE′ in FIG. 10.

FIG. 14 is a diagram illustrating a circuit board according to a third embodiment.

FIG. 15 is a cross-sectional view illustrating a semiconductor package according to the first embodiment.

FIG. 16 is a flowchart illustrating a method of manufacturing a semiconductor package according to the first embodiment.

FIG. 17 is a cross-sectional view illustrating a semiconductor package according to the second embodiment.

FIG. 18 is a plan view illustrating the semiconductor package according to the second embodiment.

FIG. 19 is a cross-sectional view illustrating a semiconductor package according to the third embodiment.

FIG. 20 is a plan view illustrating a semiconductor package according to the third embodiment.

### MODES OF THE INVENTION

The present invention may be modified into various forms and may have a variety of embodiments, and, therefore, specific embodiments will be illustrated in the drawings and described.

The embodiments, however, are not to be taken in a sense which limits the present invention to the specific embodiments and should be construed to include modifications, equivalents, or substituents within the spirit and technical scope of the present invention.

Terms including ordinal numbers such as first, second, and the like used herein may be used to describe various components, but the various components are not limited by these terms. The terms are used only for the purpose of distinguishing one component from another component. For example, without departing from the scope of the present invention, a second component may be referred to as a first component, and similarly, the first component may also be referred to as the second component. The term “and/or” includes a combination of a plurality of related listed items or any one item of the plurality of related listed items.

When a component is referred to as being “connected,” or “coupled” to another component, it may be directly connected or coupled to another component, but it should be understood that yet another component may be present between the component and another component. On the contrary, when a component is referred to as being “directly connected,” or “directly coupled” to another component, it should be understood that still another component may not be present between the component and another component.

The terms used herein are employed to describe only specific embodiments and are not intended to limit the present invention. Unless the context clearly dictates otherwise, the singular form includes the plural form. It should be understood that the terms “comprise,” “include,” and “have” specify the presence of stated herein features, numbers, steps, operations, components, elements, or combinations thereof but do not preclude the presence or possibility of adding one or more other features, numbers, steps, operations, components, elements, or combinations thereof.

Unless otherwise defined, all terms including technical or scientific terms used herein have the same meaning as commonly understood by those skilled in the art to which the present invention pertains. General terms that are defined in a dictionary should be construed as having meanings that are consistent in the context of the relevant art and are not to be interpreted as having an idealistic or excessively formalistic meaning unless clearly defined in the present application.

Hereinafter, embodiments of the present invention will be described in detail with reference to the accompanying drawings, the same reference numerals are given to the same or corresponding components regardless of drawing symbols, and a duplicate description thereof will be omitted.

Prior to describing embodiments, electronic devices to which circuit boards and semiconductor packages of the embodiments are applied will be briefly described. An electronic device includes a main board (not shown). The main board may be connected to various components physically and/or electrically. For example, the main board may be connected to the semiconductor package of the embodiment. Various semiconductor elements may be mounted in the semiconductor package.

The semiconductor element may include active elements and/or passive elements. Active elements may be semiconductor chips in the form of integrated circuits (ICs) in which hundreds or millions of components are integrated into a single chip. The semiconductor element may be a logic chip, a memory chip, etc. The logic chip may be a central processor (CPU), a graphics processor (GPU), etc. For example, the logic chip may be an application processor (AP) chip including at least one of a CPU, a GPU, a digital signal processor, a cryptographic processor, a microprocessor, and a micro controller, or an analog-to-digital converter, an application-specific IC (ASIC), or a chip set including a specific combination of the foregoing.

The memory chip may be a stack memory such as a high bandwidth memory (HBM) and the like. In addition, the memory chip may include a memory chip such as a volatile memory (e.g., a dynamic random access memory (DRAM)), a non-volatile memory (e.g., a read only memory (ROM)), and a flash memory.

Meanwhile, the product group to which the semiconductor package of the embodiment is applied may be any one of a chip scale package (CSP), a flip chip-chip scale package (FC-CSP), a flip chip ball grid array (FC-BGA), a package on package (POP), and a system in package (SIP), but the present invention is not limited thereto.

In addition, the electronic devices may be a smart phone, a personal digital assistant, a digital video camera, a digital still camera, a vehicle, a high-performance server, a network system, a computer, a monitor, a tablet, a laptop, a netbook, a television, a video game, a smart watch, an automotive, etc. However, the present invention is not limited thereto, and in addition to the electronic devices, of course, the electronic devices may be any other electronic devices that process data.

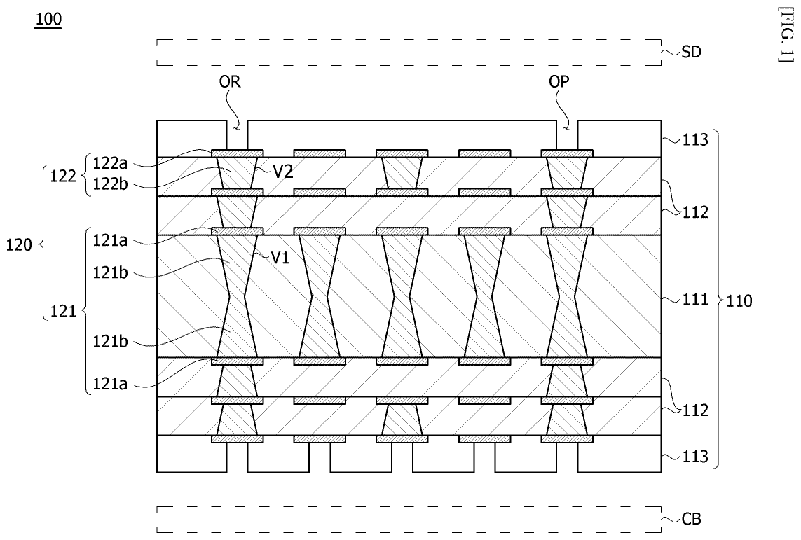

FIG. 1 is a conceptual diagram illustrating a circuit board according to an embodiment.

First, the circuit board includes electrode parts 120 for electrical connection and insulating layers 110 for preventing electrical short circuit between the electrode parts 120. Referring to FIG. 1, the insulating layer 110 includes an upper surface on which a semiconductor element is mounted and a lower surface 110B corresponding to the upper surface and for connecting a circuit board CB to a main board and the like, and may have a structure in which a plurality of insulating layers 111 and 112 are stacked between the upper surface and the lower surface. An upper insulating layer 112 constituting an upper surface of the circuit board and a lower insulating layer 112 constituting a lower surface of the circuit board may be referred to as outer stack areas, and an area stacked between the upper insulating layer and the lower insulating layer may be referred to as an inner stack area.

The electrode part 120 is disposed for electrical connection between the main board and a semiconductor element SD and includes a circuit pattern (or a circuit pattern layer), a pad, and a via electrode. In addition, the circuit pattern may be designed in various forms for the semiconductor element SD and signal and/or power transmission and is disposed in each of insulating layers 110 that are vertically stacked.

Via electrodes 121b and 122b are disposed to pass through at least a portion of each insulating layer for vertical connection between circuit patterns disposed on each of the insulating layers that are vertically stacked. That is, the insulating layer may include a via hole for arrangement of a via electrode. In addition, the via electrode may have a width that is greater than that of the circuit pattern for impedance optimization or heat dissipation, but the present invention is not limited thereto and may be designed freely.

Pads 121a and 122a may include an outer pad 122a disposed in the outer stack area and an inner pad 121a disposed in the inner stack area. The outer pad 122a functions to bond to the semiconductor element SD and/or main board or the substrate CB. Currently, the outer pad 122a may be bonded with a solder, a wire, a conductive adhesive, or the like and disposed with a width that is greater than that of the circuit pattern to solve problems such as securing yield and the like. However, the present invention is not limited thereto, and the outer pad 122a may have the same width as the circuit pattern according to the technical limitations of a bonding process. The inner pad 121a functions to connect the via electrode to the circuit pattern. When the via electrode is disposed with a width that is greater than that of the circuit pattern, during a manufacturing process of the via electrode to be disposed on each circuit pattern, a pad with a width that is greater than that of the circuit pattern is provided for position matching. Accordingly, each via electrode may have an upper surface that is located coplanar with a lower surface of the upper pad that is in direct contact with the via electrode, and a lower surface that is located coplanar with an upper surface of the lower pad that is in direct contact with a lower surface of the via electrode. Here, the lower surface of the upper pad and the upper surface of the lower pad do not necessarily mean flat surfaces, but should also be understood as a concave or convex surface that may appear according to various processes.

Alternatively, the via electrode and the pad may be integrally formed according to the process. That is, the pad may have a protrusion for electrical connection between the circuit patterns disposed in each stacked insulating layer, and the protrusion may be considered as the via electrode for electrical connection between the circuit patterns stacked adjacent to each other. That is, according to the process, the via electrode may be distinguished by different pad components or divided into protrusions of the pad.

The circuit board may further include a protective layer 113. The protective layer 113 may function to protect the pad from external moisture or contaminants and function to prevent a short circuit problem between adjacent conductive bonding members during bonding the semiconductor element and/or the main board to the circuit board. For example, the protective layer 113 may be provided as a solder resist. Specifically, the semiconductor element and/or the main board have a plurality of terminals to be connected to the circuit board. In addition, the plurality of terminals may be disposed at a high density. When the plurality of terminals and the pads of the circuit board are bonded, solder may be used as, for example, a conductive bonding material. When solder is used, a solder short circuit problem may occur between the terminals with a high density, and thus a solder resist having poor wetting properties with a solder may be disposed in order to address this solder short circuit problem. In addition, the protective layer 113 may be made of a material with insulation for an electrical connection. Thus, the protective layer 113 may be referred to as an “insulating layer” and may be one component of the insulating layer 110.

In addition, the insulating layer 112 or the protective layer 113 located in the outer stack area of the circuit board may have an opening OP. Other semiconductor elements, circuit boards, or the like are elctrically connected through the opening OP.

The circuit board may be divided into a package substrate and an interposer according to functions. The package substrate functions for mounting a semiconductor element and/or an interposer. As data increases, an area of the circuit board may expand or the stack number of insulating layers may increase, which may significantly reduce a yield of the circuit board. Therefore, in order to improve the yield of the circuit board with a high stack number, the circuit board is separated into an interposer and a package substrate, which may improve the yield of the circuit board. In addition, the interposer may serve as a buffer between a pad size and/or gap of the package substrate and a fine pattern size and/or gap of the terminals of the semiconductor element. Specifically, as the gap and size of the terminals of semiconductor elements become smaller and the density of the terminals increases, it may be difficult to implement pads of a package substrate, which have sizes and/or gaps corresponding to the terminals of the semiconductor element. Therefore, an interposer having a size and/or a gap of a pad between the size and/or gap of the pad of the package substrate and the size and/or gap of the terminal of the semiconductor element is disposed, it is possible to facilitate electrical connection between the semiconductor element and the package substrate.

The above-described package substrate and interposer may be classified into a core substrate and a coreless substrate, respectively, according to the composition of the insulating layer. In the case of a core substrate, the insulating layer may include a core layer, and the core layer may be a layer including a reinforcing member among the stacked insulating layers. The reinforcing member may be glass fiber. The core layer may be disposed to be thicker than other insulating layers to have a function of preventing the circuit board from being bent during the process. However, the core layer may cause problems such as voltage drop and signal loss and may be difficult to thin. Therefore, according to application fields, a coreless substrate not including a core layer may be used as the insulating layer of the circuit board.

The insulating layer of the circuit board is made of any insulating resin, such as a thermosetting and/or photocurable resin. As a thermosetting resin, ajinomoto build-up film (ABF) that is a product released by Ajinomoto Co., Inc. may be used, and materials such as prepreg (PPG) containing glass fiber may be used. Any insulating resin, such as a photo imageable dielectric (PID) resin, may be used as a photocurable resin. The above-described insulating resin may be, for example, an epoxy resin, a bismaleimide triazine resin (BT resin), a phenol resin, or the like, and may include an inorganic filler such as silica. When an insulating resin is used as a core, a reinforcing member made of glass fiber or aramid fiber may be included.

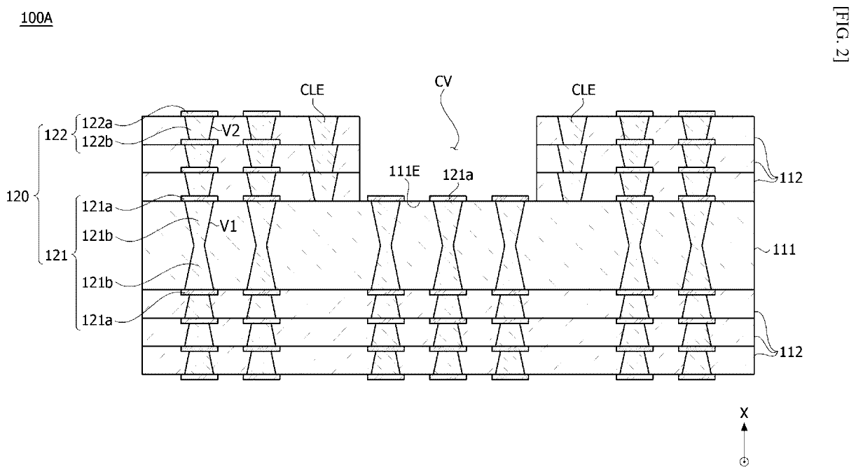

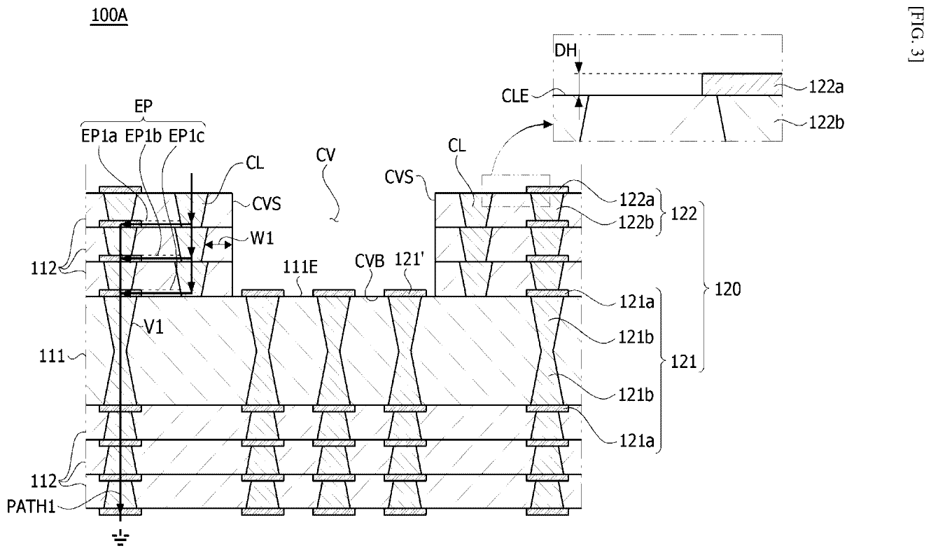

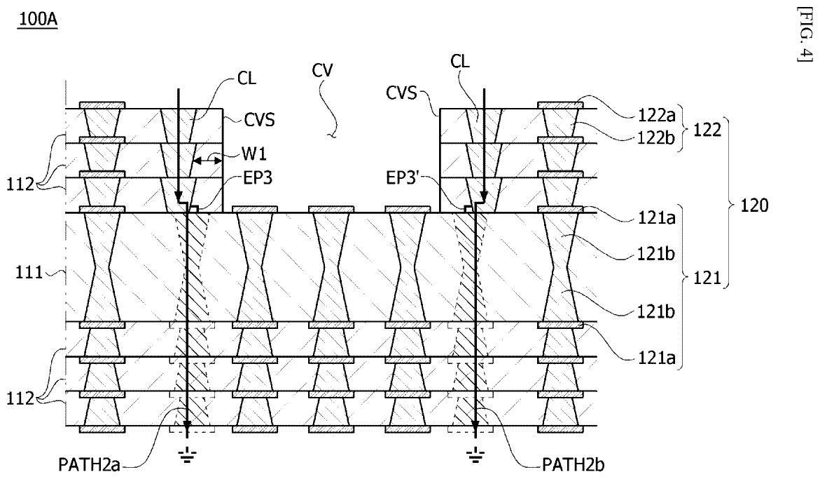

FIG. 2 is a diagram illustrating a circuit board according to a first embodiment, FIG. 3 is an enlarged diagram illustrating a portion of FIG. 2, and FIG. 4 is a diagram illustrating a modified example of FIG. 3.

Referring to FIGS. 2 and 3, a circuit board 100A according to the embodiment may include an insulating layer 110, an electrode part 120, and a connection layer CL. In each embodiment, the above-described contents in FIG. 1 may be applied to the insulating layer and the electrode part, except for the description below.

The circuit board 100A according to the embodiment may include a second insulating layer 112 including a cavity CV. In the circuit board of the embodiment according to the present invention, a circuit pattern layer may refer to a concept including the circuit pattern and the pad described in FIG. 1.

First, the insulating layer 110 may be made of an insulating material. The insulating layer 110 may be formed of at least one layer. When the insulating layer 110 has a structure of a plurality of layers, the plurality of the insulating layers 110 may include the same insulating material, but the resent invention is not limited thereto. For example, at least one insulating layer 110 of the plurality of the insulating layers 110 may include a different insulating material from that of at least one other insulating layer 110.

The insulating layer 110 of the circuit board 100A may be rigid or flexible. For example, the insulating layer 110 of the circuit board 100A may include glass or plastic. For example, the insulating layer 110 of the circuit board may include chemically tempered glass/semi-tempered glass such as soda lime glass or aluminosilicate glass. For example, the insulating layer 110 of the substrate may include a reinforced or flexible plastic such as polyimide (PI), polyethylene terephthalate (PET), propylene glycol (PPG), or polycarbonate (PC). For example, the insulating layer 110 of the circuit board may include sapphire. For example, the insulating layer 110 of the substrate may include an optically isotropic film. For example, the insulating layer 110 of the substrate may include a cyclic olefin copolymer (COC), a cyclic olefin polymer (COP), an optically isotropic PC, or an optically isotropic polymethyl methacrylate (PMMA). For example, the insulating layer 110 of the substrate may be formed of a material containing a filler and an insulating resin. For example, the insulating layer 110 of the substrate may have a structure in which a filler of silica or alumina is disposed in a thermosetting resin or a thermoplastic resin.

The insulating layer 110 may have a structure in which a plurality of different insulating materials are stacked, and an exemplary arrangement structure will be described in more detail as follows.

In one embodiment, the insulating layer 110 may include a core layer or a coreless layer including a reinforcing member. Here, the core layer may be an insulating layer including a reinforcing member and having a thickness exceeding 30 μm in a stack direction (X-axis direction). In addition, the insulating layer may include a plurality of layers, each of which is disposed above and below the core layer and does not include a reinforcing member. In this case, the circuit board may be a core substrate. The reinforcing member may also be referred to as reinforced fiber or glass fiber.

The reinforcing member may refer to a glass fiber material extending in a horizontal direction of the insulating layer and may have a different meaning from fillers spaced apart from each other.

In another embodiment, the insulating layer 110 of the substrate may be a coreless substrate that does not include a core layer. For example, the insulating layer 110 of the substrate may include an organic material that does not include a reinforcing member, which allows for excellent processability, slimness of the substrate, and fineness of the electrode part of the substrate. For example, the insulating layer 110 of the substrate may be made of an ABF that is a product released by Ajinomoto Co., Inc., FR-4, a BT, a PID resin, BT, or the like. For example, the insulating layer 110 may include a plurality of layers made of ABF.

In an embodiment, the insulating layer 110 may include a first insulating layer 111 and a second insulating layer 112. The second insulating layer 112 may be disposed on the first insulating layer 111.

The first insulating layer 111 may be a portion of a copper clad laminate (CCL). Alternatively, the first insulating layer 111 may correspond to the CCL. For example, the first insulating layer 111 and the first electrode part 121 located in the first insulating layer 111 may each be the CCL. The first insulating layer 111 and a first circuit pattern layer 121a may each be the CCL.

In addition, the first insulating layer 111 may include an insulating material from the circuit board 100A to an inner layer stack area. The first insulating layer 111 may be formed of a plurality of layers, and the plurality of layers may be formed of the same material or different materials. A boundary surface of the second insulating layer 112 above the first insulating layer 111 may be divided or may not be divided according to an analysis method. The description of the boundary surface may be equally applied to each insulating layer in the first and second insulating layers. In addition, the first insulating layer 111 may be positioned between upper and lower second insulating layers 112. The second insulating layer 112 may be disposed on an upper surface and a lower surface of the first insulating layer 111.

The first insulating layer 111 and the first electrode part 121 may not be easily removed by etching according to an etching process when the cavity is formed. That is, even when the cavity CV is formed in the second insulating layer 112, the first insulating layer 111 and the first electrode part 121 may remain easy.

In addition, the second insulating layer 112 may be disposed on the first insulating layer 111 and the first circuit pattern layer 121a. The second insulating layer 112 may correspond to an outer layer stack area of the circuit board 110A.

The second insulating layer 112 may be formed of at least one layer. As shown in the drawing, the second insulating layer 112 may be formed of a plurality of layers. In addition, as described above, the second insulating layer 112 may include an ABF or PPG including glass fiber.

The second insulating layer 112 may be located on at least one of the upper surface and the lower surface of the first insulating layer 111. Hereinafter, a description will be made based on the stack direction (X-axis direction).

In addition, as described above, a third insulating layer (not shown) may be further disposed on the second insulating layer 112. The third insulating layer (not shown) may be a resist layer. The resist layer may have a function of preventing solder from flowing during solder bonding by having low solder wettability or may have a function of preventing moisture or contaminants from the outside from infiltrating into the circuit board.

In addition, the third insulating layer (not shown) may be a solder resist layer containing an organic polymer material. For example, the third insulating layer (not shown) of the circuit board may include a resin, a curing agent, a photo-initiator, a pigment, a solvent, a filler, an additive, an acryl-based monomer, and the like. In addition, the third insulating layer (not shown) may include any one of a photo solder resist layer, a cover-lay, and a polymer material.

The electrode part 120 may include a first electrode part 121, and a second electrode part 122. The first electrode part 121 may be located in the first insulating layer 111. The second electrode part 122 may be located in the second insulating layer 112.

The first electrode part 121 may include a first circuit pattern layer 121a and a first via electrode 121b. The second electrode part 122 may include a second circuit pattern layer 122a and a second via electrode 122b. As described above, each circuit pattern layer may include a pad and/or a trace of the electrode part and a circuit pattern. In addition, the circuit pattern layer may be disposed in each of the stacked insulating layers, and for electrical connection between the circuit pattern layers disposed in each of the stacked insulating layers, the via electrode may be disposed between the plurality of circuit pattern layers disposed in different layers. In addition, the through electrode may electrically connect the plurality of circuit pattern layers disposed in different layers.

The first circuit pattern layer 121a may be disposed on the first insulating layer 111. The first circuit pattern layer 121a may be disposed on the upper surface and a lower surface of the first insulating layer 111. The first through electrode 121b may pass through the first insulating layer 111 and may be in contact with the first circuit pattern layer 121a.

The second circuit pattern layer 122a may be disposed on the second insulating layer 112. The second circuit pattern layer 122a may be disposed on an upper surface and a lower surface of the second insulating layer 112. The second through electrode 122b may pass through the second insulating layer 112 and may be in contact with the second circuit pattern layer 122a.

In this way, the first circuit pattern layer 121a and the second circuit pattern layer 122a may be located on the first insulating layer 111 and the second insulating layer 112. As described above, since the circuit pattern layer refers to a concept including a circuit pattern and a pad, the circuit pattern layer may be located in each insulating layer and may not be directly connected to the via electrode or the through electrode. However, each circuit pattern layer may be electrically connected to any one via electrode.

In addition, the first insulating layer 111 and the second insulating layer 112 may include vias or through-holes V1 and V2. The through-hole may include a first through-hole V1 passing through the first insulating layer 111 and a second through-hole V2 passing through the second insulating layer 112. In addition, the through-electrodes of the electrode part may be located in the through-holes V1 and V2. For example, the first via electrode 121b may be located in the first through-hole V1. The second via electrode 122b may be located in the second through-hole V2.

In an embodiment, the first through-hole V1 of the first insulating layer 111 and the second through-hole V2 of the second insulating layer 112 may have inclined surfaces in the stack direction. That is, an area of the first through-hole V 1 and the second through-hole V 2 adjacent to each other may increase or decrease in one direction. For example, the area of the first through-hole V1 and the second through-hole V2 may increase in the stack direction based on an upper region in the circuit board 100A. Here, the upper region of the circuit board 100A corresponds to a region in the stack direction among regions obtained by bisecting the first insulating layer 111 in the stack direction.

In addition, since the second insulating layer 112 is formed of a plurality of insulating layers, the second through-hole V2 may also be provided as a plurality of second through-holes V2. Each of the plurality of second through-holes V2 may have an area that increases or decreases in one direction. The areas of the plurality of second through-holes V2 may increase in the stack direction based on the upper region in the circuit board 100A.

In addition, the second insulating layer 112 may cover at least a portion of the first circuit pattern layer 121a. In addition, the third insulating layer (not shown) may cover at least a portion of the second circuit pattern layer 122a. The third insulating layer (not shown) may include an opening for electrical connection with a semiconductor element, an interposer, and the like. The second circuit pattern layer 122a may be exposed by the opening. A shield layer, which will be described below, may be located on the third insulating layer.

The second insulating layer 112 may include a cavity CV. The second insulating layer 112 may include the cavity CV and an edge portion outside the cavity CV. The edge portion may correspond to a “rim portion,” a “wall portion,” a “sidewall,” or the like. Furthermore, the second electrode part 122 may be located in the edge portion. In the embodiments of the present invention, the cavity CV may be variously expressed, such as a “groove,” a “recess,” a “hole,” and a “via.” Furthermore, the cavity CV may have various shapes such as a circular shape, a quadrangular shape, and the like.

The cavity CV may be located in the second insulating layer 112. That is, the cavity CV may be located on the first insulating layer 111 and the first electrode part 121.

In addition, the cavity CV may have various shapes according to a shape of a semiconductor element or chip mounted therein. For example, the shape of the semiconductor element or chip may be generally a quadrangular shape with respect to a surface perpendicular to the stack direction. Correspondingly, the cavity CV may also have a quadrangular shape with respect to a surface perpendicular to the stack direction.

In addition, since the second electrode part 122 is disposed in the second insulating layer 112 outside the cavity CV while securing a mounting space of the semiconductor element or chip in the cavity CV, a circuit pattern having a small line width may be easily disposed in the second insulating layer 112. Accordingly, the circuit board according to the embodiment may provide an improved input/output (I/O) count.

A portion 111E of the first insulating layer may be exposed by the cavity CV. A portion 121E of the first circuit pattern layer 121a may be exposed by the cavity CV.

In addition, at least a portion of the first circuit pattern layer 121a may be exposed by the cavity CV.

The connection layer CL may pass through the second insulating layer 112. The connection layer CL is a member for electromagnetic wave shielding and may include a conductive material. Accordingly, the connection layer may be referred to as a “shielding member,” a “shielding layer,” a “blocking member,” or a “blocking layer.” Furthermore, the connection layer CL may have the same material as or similar shape to the via electrode. In addition, as will be described below, the connection layer CL may be connected to the ground or at least a portion of the connection layer CL may be in a state of dummy or floating.

Furthermore, the connection layer CL is similar to the via electrode, but a height of the connection layer CL may be the same as or different from that of the via electrode according to whether the pad is present in the stack direction. For example, when a pad buried in the second insulating layer is present, the height of the connection layer CL in the stack direction may be greater than a height of the via electrode in the stack direction. The height of the connection layer CL in the stack direction may be different from the height of the via electrode in the stack direction.

As a modified example, the connection layer CL may pass through a portion of the second insulating layer 112. In addition, the connection layer CL may pass through the second insulating layer 112 while passing through a portion of the first insulating layer 111. For example, the connection layer CL may be formed of a plurality of sub-connection layers spaced apart from each other. In addition, some of the plurality of sub-connection layers may pass through the second insulating layer 112, and the remaining of the plurality of sub-connection layers may pass through at least a portion of the second insulating layer 112 or at least a portion of the first insulating layer 111. However, in consideration of the easiness of the manufacturing process, at least a portion of the connection layer CL may pass through the second insulating layer 112. This will be described below. In addition, when the cavity is formed, the connection layer may be formed simultaneously. Accordingly, the easiness of manufacture can be improved. Alternatively, the connection layer may be formed in a different operation from the cavity.

Similar to the second electrode part 122, the connection layer CL may be made of a conductive material. Accordingly, the connection layer CL may be electrically connected to the shield layer disposed on the circuit board 100A. Therefore, the connection layer CL may be connected to the ground in the package substrate and may serve a function of a “shielding layer,” a “blocking layer,” or an “electromagnetic wave blocking layer” performing an electromagnetic wave shielding (MEI) function. Furthermore, the cavity CV may be as an empty space to facilitate passage of electromagnetic waves. Accordingly, by disposing the connection layer CL that performs a shielding function on an outer side of the cavity CV, electromagnetic interference (EMI) of the semiconductor element or chip in the cavity CV may be more effectively performed.

Furthermore, the second electrode part disposed on the second insulating layer 112 is various signal lines, and the connection layer CL may be disposed in the second insulating layer to effectively block EMI that occurs in the signal lines.

The connection layer CL may be disposed along an edge of the cavity CV while being disposed on the second insulating layer 112. The connection layer CL may overlap the second circuit pattern layer 122a at the outer side of the cavity CV in a direction perpendicular to the stack direction. That is, the connection layer CL may be located in the same layer as the second electrode part 122 in the second insulating layer 112. Alternatively, the connection layer CL may be disposed in the same layer as at least a portion of the second electrode part 122 in the second insulating layer 112. Accordingly, at least a portion of the second electrode part 122 may overlap the connection layer CL in a horizontal direction perpendicular to the stack direction.

Furthermore, the connection layer CL may be located between the second electrode part 122 and the cavity CV or located at the outer side of the second electrode part 122. Alternatively, the connection layer CL may be located between the second electrode parts 122 spaced apart from each other in the second insulating layer 112. By applying the structure, the connection layer CL may prevent electromagnetic interference generated in the circuit board out of or externally generated from being introduced into the cavity. In addition, noise due to electromagnetic waves may be reduced.

The connection layer CL may block an electromagnetic force applied to the semiconductor element or chip mounted in the cavity CV. In other words, a shielding function of the connection layer CL may be effectively provided.

In addition, the connection layer CL may be located at an outer side of at least a portion of the second electrode part 122 so that electrical reliability of the second electrode part 122 can be improved.

In addition, as described above, the connection layer CL may pass through the second insulating layer 112 to be in contact with an upper surface of the first insulating layer 111. Thus, the connection layer CL may overlap the semiconductor element or chip in the horizontal direction. Accordingly, electromagnetic shielding for the semiconductor element or chip may be effectively performed.

In addition, the connection layer CL may be disposed to be spaced apart from a side surface CVS of the cavity CV. In addition, since the connection layer CL is spaced apart from the side surface CVS of the cavity CV by a predetermined distance W1, generation of an electrical issue (e.g., a short circuit) with respect to the semiconductor element or chip mounted inside the cavity CV may be suppressed. Here, the predetermined distance W1 may a shortest distance between the side surface CVS of the cavity CV and the connection layer CL in the horizontal direction. When the connection layer CL is made of a conductive material and has an inclined side surface, the predetermined distance W1 for electromagnetic wave shielding is provided and defined as the shortest distance between the conductive material and the side surface CVS of the cavity CV in the horizontal direction so that position accuracy of the cavity CV may be adjusted more precisely.

Furthermore, a bottom surface CVB of the cavity CV may correspond to the exposed upper surface 111E of the first insulating layer. In addition, the bottom surface CVB of the cavity CV may correspond to an exposed first electrode part 121′ or the exposed first circuit pattern layer. Accordingly, an electrical connection between the semiconductor element or chip mounted in the cavity CV and the second electrode part 122 may be easily performed.

Since the connection layer CL passes through the second insulating layer 112, an upper portion may be partially exposed. An exposed upper surface CLE of the connection layer CL may be disposed and spaced apart from the upper surface of the first circuit pattern layer 122a disposed on the upper surface of the second insulating layer 112. For example, the exposed upper surface CLE of the connection layer CL may be disposed and spaced apart from the upper surface of the first circuit pattern layer 122a disposed on the upper surface of the second insulating layer 112 by a predetermined distance DH in the stack direction. In addition, the exposed upper surface CLE of the connection layer CL may be located below the upper surface of the first circuit pattern layer 122a located on the upper surface of the second insulating layer 112. For example, the exposed upper surface CLE of the connection layer CL may be located adjacent to the first insulating layer 111 compared to the upper surface of the first circuit pattern layer 122a disposed on the upper surface of the second insulating layer 112.

In addition, the connection layer CL according to the embodiment may be electrically connected to the second electrode part 122. For example, the connection layer CL may be electrically connected to the second circuit pattern layer 122a. To this end, in the circuit board 100A according to the embodiment, the connection layer CL may be electrically connected to the second electrode part 122 through an extension.

The circuit board 100A may include a first extension EP1 for electrical connection. The first extension part EP1 may be in contact with the connection layer CL and the second electrode part 122 and may be electrically connected to the connection layer CL and the second electrode part 122.

The first extension EP1 may be located in the second insulating layer 112. In addition, the first extension EP1 may extend in a direction perpendicular to the stack direction. Thus, the first extension EP1 may connect the connection layer CL and the second circuit pattern layer 122a. Accordingly, the first extension EP1 may overlap the second electrode part 122 or the connection layer CL in the second insulating layer 112 in a direction perpendicular to the stack direction.

For example, the first extension EP1 may include at least one of a 1-1 extension EP1a, a 1-2 extension EP1b, and a 1-3 extension EP1c. Each of the 1-1 extension EP1a, the 1-2 extension EP1b, and the 1-3 extension EP1c may be located in one layer of the second insulating layer 112 formed of a plurality of layers. Accordingly, the first extension EP1 may be easily electrically connected to the second electrode part 122.

In addition, any one of the 1-1 extension EP1a, the 1-2 extension EP1b, and the 1-3 extension EP1c may be located in a region inside the second insulating layer 112. In other words, the connection layer CL may be in contact with and electrically connected to the second electrode part 122 through the 1-1 extension EP1a, the 1-2 extension EP1b, and the 1-3 extension EP1c, which are a plurality of contact points. Accordingly, even when an electrical issue occurs in any one of the 1-1 extension EP1a, the 1-2 extension EP1b, and the 1-3 extension EP1c, an electrical connection between the connection layer CL and the second electrode part 122 may be maintained. In addition, the 1-1 extension EP1a, the 1-2 extension EP1b, and the 1-3 extension EP1c may be electrically connected to the first electrode part 121. For example, the 1-1 extension EP1a, the 1-2 extension EP1b, and the 1-3 extension EP1c may be electrically connected to any one of the first electrode parts 121. In other words, the electromagnetic wave shielding may be more reliably maintained.

In addition, the first electrode part 121 connected to the first extending portion EP1 may be electrically connected to a ground of the substrate. Accordingly, the connection layer CL, the first extension EP1, the second electrode part, and the first electrode part may be electrically connected (PATH1). Furthermore, the first extension EP1 may also be located in the same layer as the second insulating layer 112 in the second electrode part 122. Thus, the first extension EP1 may be in contact with the electrode part closest to the first extension EP1 of the second electrode parts 122. Accordingly, a circuit of the second extension EP1 may be easily formed.

In addition, the first extension EP1 may be formed to have the same shape as a trace or pad of the electrode part. Accordingly, the first extension EP1 may be formed on the same layer as the pad of the second electrode part or the second circuit pattern layer to overlap the pad or the second circuit pattern layer in a direction perpendicular to the stack direction. For electrical connection, the first extension EP1 may be formed of a conductive material.

Referring further to FIG. 4, in a modified example, the circuit board may include a second extension EP3. The second extension EP3 may be in contact with the connection layer CL and the first electrode part 121 and may be electrically connected to the connection layer CL and the first electrode part 121.

The second extension EP3 may be located inside the first insulating layer 111. In the present embodiment, the extension may be a trace or pad electrically connected to the ground of the substrate. In addition, the second extension EP3 may extend in the stack direction or a direction perpendicular to the stack direction. Accordingly, the second extension EP3 may connect the connection layer CL and the first circuit pattern layer 121a. Thus, the second extension EP3 may overlap the first electrode part 121 or the connection layer CL inside the first insulating layer 111 in a direction perpendicular to the stack direction.

For example, at least one of the second extension EP3 may be present at least one of various positions inside the first insulating layer 111. Accordingly, the second extension EP3 may be easily electrically connected to the first electrode part 121. In addition, a portion of the second extension EP3 may be located in some region in the first insulating layer 111. In other words, the connection layer CL may be connected to the first electrode part 121 through a plurality of contact points. Accordingly, even when an electrical issue occurs in a portion of the second extension EP3 or a portion of the first electrode part 121, an electrical connection between the connection layer CL and the first electrode part 121 may be maintained. In other words, reliability of the electromagnetic wave shielding may be maintained higher.

The first electrode part 121 connected to the second extension EP3 may be electrically connected to the ground of the substrate. Accordingly, the connection layer CL, the second extension EP3, and the first electrode part 121 may be electrically connected (PATH2a and PATH2b). In addition, as described above, a plurality of electrical connection paths (PATH2a and PATH2b) may be formed by a plurality of contact points. Thus, retentivity or reliability for the electromagnetic wave shielding may be more effectively performed.

In addition, the second extension EP 3 may be formed to have the same shape as the trace or pad of the electrode part. Accordingly, the second extension EP 3 may be formed on the same layer as the pad of the second electrode part or the second circuit pattern layer to overlap the pad or the second circuit pattern layer in a direction perpendicular to the stack direction. For electrical connection, the second extension EP 3 may be made of a conductive material.

In addition, as another example, the connection layer CL may be in direct contact with the first electrode part 121. For example, the connection layer CL may at least partially overlap the first electrode part 121 in the stack direction. Accordingly, a contact between the connection layer CL and the first electrode part 121 may be more easily achieved.

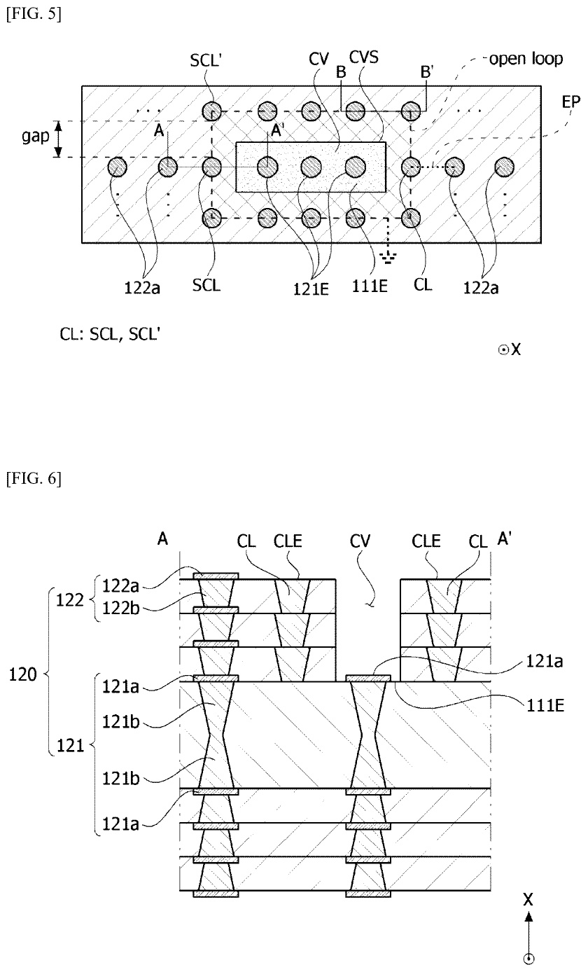

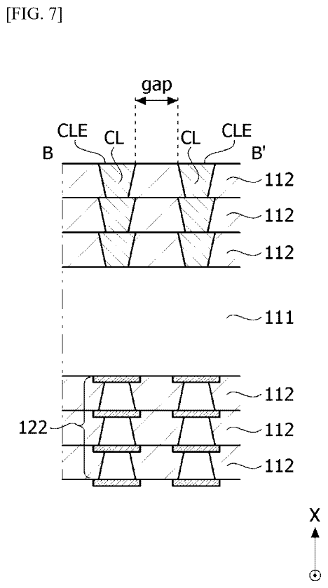

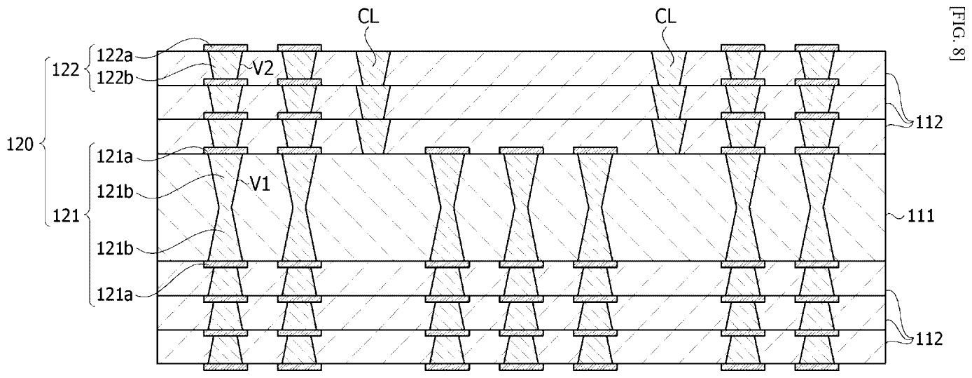

FIG. 5 is a plan view of the circuit board according to the first embodiment, FIG. 6 is a diagram along line AA′ in FIG. 5, and FIG. 7 is a diagram along line BB′ in FIG. 5.

Referring to FIGS. 5 to 7, in the circuit board according to the embodiment, the connection layer CL may surround the cavity CV in the form of an open loop or a closed loop. For example, the connection layer CL may surround the cavity CV in the form of an open loop.

Accordingly, a plurality of connection layers CL may be disposed and spaced apart from each other. The connection layer CL may include a first sub-connection layer SCL and a second sub-connection layer SCL′. The first sub-connection layer SCL and the second sub-connection layer SCL′ may be disposed and spaced apart from each other by a predetermined distance gap in a direction perpendicular to the stack direction. In addition, both the first sub-connection layer SCL and the second sub-connection layer SCL′ may not be in contact with the first extension or the second electrode part. However, the first sub-connection layer SCL and the second sub-connection layer SCL′ may be electrically connected to each other even when the first sub-connection layer SCL and the second sub-connection layer SCL′ are not in contact with each other. Accordingly, an electromagnetic shielding function by the connection layer CL surrounding the cavity CV may exhibit.

In addition, the connection layer CL may be located between the second electrode part 122 and the cavity CV or located at the outer side of the second electrode part 122. In addition, the connection layer CL may be located between the second electrode parts 122 spaced apart from each other in the second insulating layer 112. That is, the connection layer CL may be located at an outer side of at least a portion of the second electrode part 122. Furthermore, as described above, an area of the cavity CV as a surface or a flat surface perpendicular to the stack direction may be smaller than an area of the open loop formed by the connection layer CL.

Furthermore, since the connection layer CL is located at the outer side of the cavity CV, the connection layer CL may suppress warpage of the circuit board due to thermal expansion or the like.

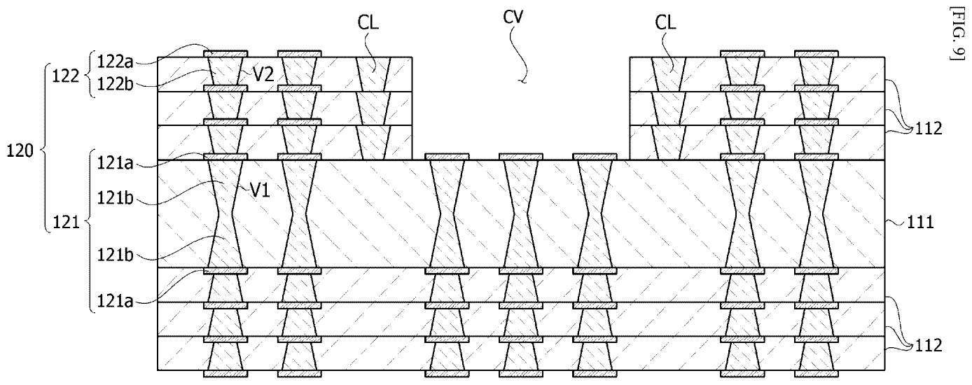

FIGS. 8 and 9 are flowcharts illustrating a method of manufacturing a circuit board according to the first embodiment.

Referring to FIG. 8, a copper-clad laminate having copper foils on both surfaces including the first insulating layer 111 is provided. In addition, a via hole or a through-hole may be formed in the first insulating layer 111. The through-hole or the via hole may be formed by a method such as a laser drilling method, a punching method, an etching method (mechanical drilling, chemical etching, or any suitable mechanism), and the like.

In addition, a first via electrode may be formed in a first through-hole. Thereafter, a first circuit pattern layer may be formed on the first insulating layer 111 through patterning.

In addition, the second insulating layer 112 may be stacked on both surfaces of the first insulating layer 111. In addition, a through-hole or a via hole may be formed with respect to the second insulating layer, and a second via electrode may be formed. However, one region of the second insulating layer 112 may be formed of only the insulating layer without the second electrode part. This one region may correspond to a region of the above-described cavity. Furthermore, the connection layer CL may also be located in the second insulating layer 112.

Each circuit pattern layer may be formed by an additive process, a subtractive process, a modified semi additive process (MSAP), a semi additive process (SAP) method, or the like, which is a manufacturing process of a printed circuit board substrate.

Furthermore, the pattern may be formed by a dry film or the like.

Referring to FIG. 9, the cavity CV may be formed inside the second insulating layer 112 by a method such as a laser method, a punching method, and an etching method for the one region described above. The cavity CV may pass through a central region of the second insulating layer 112. The cavity CV may be surrounded by the second electrode part. In addition, the cavity CV may be surrounded by the connection layer CL. In other words, the cavity CV may be located in the connection layer CL and the second electrode part. A portion of the first insulating layer 111 and a portion of the first electrode part 121 may be exposed by the cavity CV.

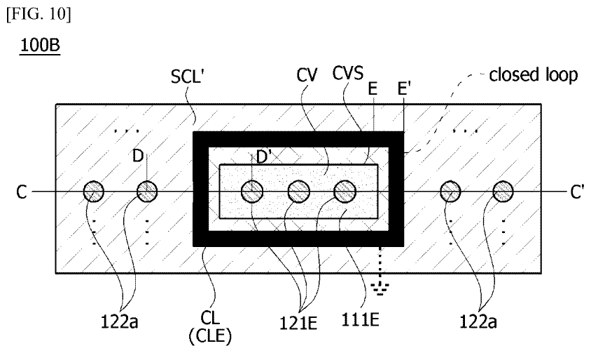

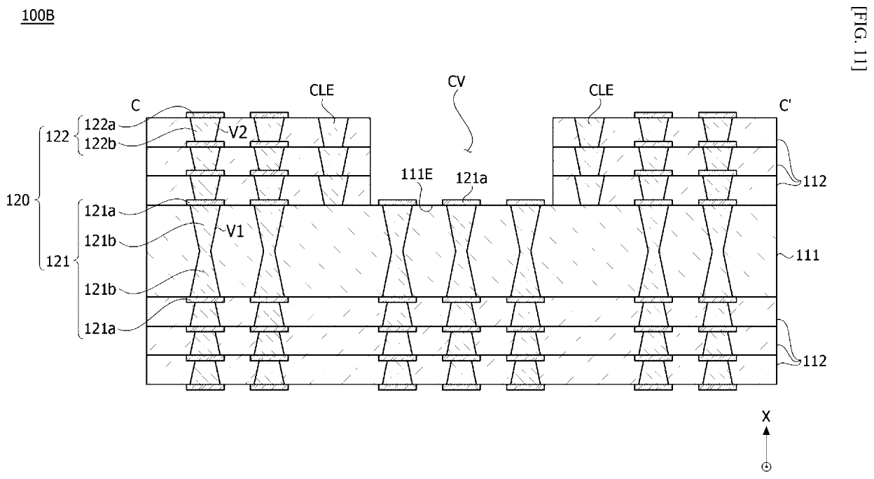

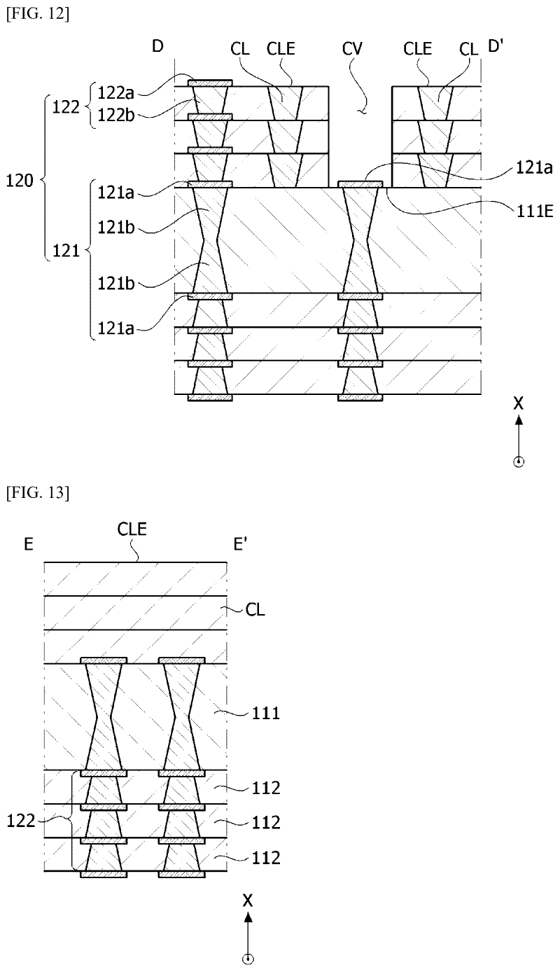

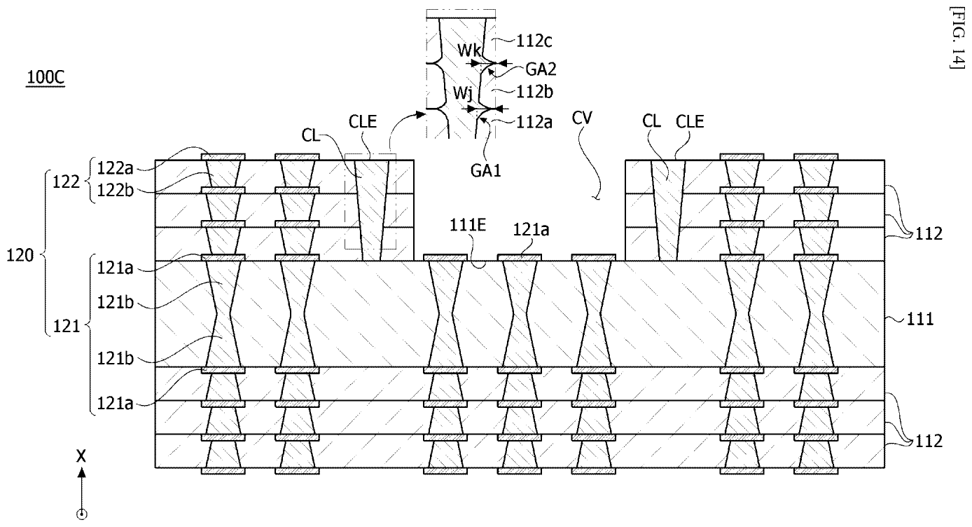

FIG. 10 is a plan view of the circuit board according to a second embodiment, FIG. 11 is a diagram along line CC′ in FIG. 10, FIG. 12 is a diagram along line DD′ in FIG. 10, and FIG. 13 is a diagram along line EE′ in FIG. 10.

Referring to FIGS. 10 to 13, a circuit board 100B according to a second embodiment may include an insulating layer 110, an electrode part 120, and a connection layer CL. The above description may be equally applied except for the contents which will be described below.

In the circuit board 100B according to the second embodiment, the connection layer CL may surround a cavity CV in the form of a closed loop. Accordingly, the connection layer CL may continuously surround the cavity CV. At least a portion of the connection layer CL may be in direct contact with a first extension, a second electrode part, a first electrode part, or a second electrode part. For example, the connection layer CL may be electrically connected to the first extension, the second electrode part, and the first electrode part. Alternatively, the connection layer CL may be electrically connected to the second electrode part. In addition, the connection layer CL may be electrically connected to the second electrode part and the second extension. Accordingly, an electromagnetic shielding function by the connection layer CL surrounding the cavity CV may exhibit.

In addition, the connection layer CL may be located between the second electrode part 122 and the cavity CV or located at the outer side of the second electrode part 122. In addition, the connection layer CL may be located between the second electrode parts 122 spaced apart from each other in the second insulating layer 112. That is, the connection layer CL may be located at an outer side of at least a portion of the second electrode part 122. Furthermore, as described above, an area of the cavity CV as a surface or a flat surface perpendicular to the stack direction may be smaller than an area of the closed loop formed by the connection layer CL.

In addition, the connection layer CL may be maintained in length in the stack direction or may be different in some regions. For example, the length of the connection layer CL in the stack direction may be changed at an edge of the closed loop. For example, as a separation distance between the connection layer CL and the cavity CV increases, the length of the connection layer CL in the stack direction may increase.

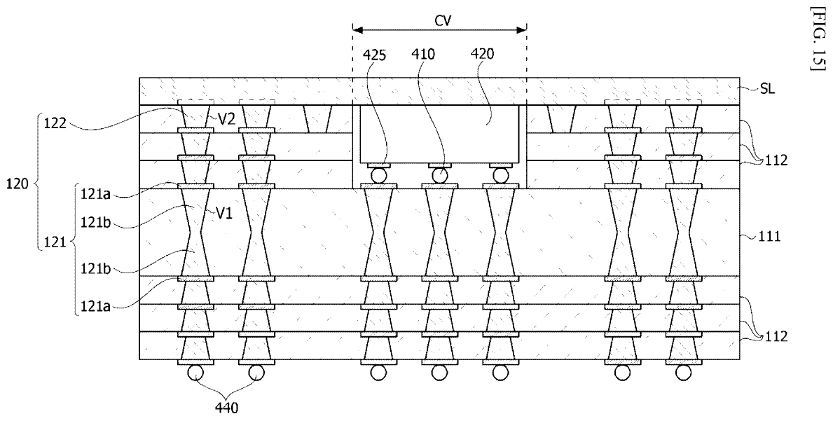

FIG. 14 is a diagram illustrating a circuit board according to a third embodiment.

The circuit board 100C according to the third embodiment may include an insulating layer 110, an electrode part 120, and a connection layer CL. The above description may be equally applied except for the contents which will be described below.

In the circuit board 100C according to the third embodiment, the connection layer CL may be located in the second insulating layer 112. The connection layer CL may pass through the second insulating layer 112.

The connection layer CL may have a shape different from a shape of a second electrode part 122 of the second insulating layer 112 formed of a plurality of layers. In the second electrode part 122, a through electrode 122b may be located in each layer of the second insulating layer 112. Accordingly, a width (or area) of the through electrode 122b in each layer may increase or decrease in the stack direction. For example, a width (or area) of the through electrode 122b may be the same at a lower portion of each layer. Alternatively, the width (or area) of the through electrode 122 b may be similar within 20% to each other at a lower portion of each layer. In addition, the width (or area) of the through electrode 122b may be the same at an upper portion of each layer. Alternatively, the width (or area) of the through electrode 122b may be similar within 20% to each other at a lower portion of each layer.

In addition, the connection layer CL may continuously pass through at least two of the layers of the second insulating layer 112. Accordingly, a minimum width (or area) of the connection layer CL may be smaller than a minimum width (or area) of the through electrode 122b.

In addition, as described above, the second insulating layer 112 may be formed of a plurality of layers. For example, the plurality of layers of the second insulating layer 112 may include a 2-1 insulating layer 112a, a 2-2 insulating layer 112b, and a 2-3 insulating layer 112c.

In addition, in the embodiment, a groove extending to the outer side of the connection layer CL may be present on a boundary surface between the insulating layers. The groove may be located at a boundary surface between adjacent insulating layers. In addition, the groove may be a portion formed on the boundary surface of the adjacent insulating layers when the through-hole passing through the plurality of insulating layers is formed.

In addition, the groove may is not present in a portion of the boundary surface of the adjacent insulating layers. Hereinafter, a description will be made based on the presence of the groove on the boundary surface between the insulating layers in the second insulating layer 112.

For example, a first groove GA1 may be located between the 2-1 insulating layer 112a and the 2-2 insulating layer 112b. In addition, a second groove GA2 may be located between the 2-2 insulating layer 112b and the 2-3 insulating layer 112c.

In addition, at least a portion of the connection layer CL may also be present in the groove formed in the boundary surface of each insulating layer. For example, when a through-hole passing through the second insulating layer 112 formed of the plurality of insulating layers is formed, a portion of the through-hole extending from the second insulating layer 112 to the boundary surface between adjacent insulating layers may correspond to the groove. After the through-hole and the groove are formed, the groove is filled with the connection layer CL. For example, the connection layer CL may be located in the first groove GA1. In addition, the connection layer CL may be located in the second groove GA2.

In addition, grooves formed on the boundary surface of the adjacent insulating layers may have the same width or different widths according to their positions. For example, a width Wj of the first groove GA1 may vary according to the position on a plane. Similarly, a width Wk of the second groove GA2 may vary according to a position on a plane. Furthermore, the width Wj of the first groove GA1 and the width Wk of the second groove GA2 may be the same as or different from each other.

In addition, the connection layer CL may be located in the groove and may be located in at least a portion of the groove. For example, the grooves GA1 and GA2 may be filled with the connection layer CL. In addition, at least a partial area of each of the grooves GA1 and GA2 may be filled with the connection layer CL. Accordingly, a gap may be present between a side surface of the groove and the connection layer CL in each of the grooves GA1 and GA2. For example, air may be present.

In addition, the connection layer CL may be electrically connected to the first and second electrode parts through the first extension or the second extension. In addition, a separation distance between the connection layer CL and an adjacent second electrode part may increase or decrease as the connection layer CL faces one direction (lower). For example, the connection layer CL may be formed to be different from the number of layers of the second insulating layer. The connection layer CL may have a structure in which an area, a size, or a width decreases toward a lower portion of the substrate or the first insulating layer. With this configuration, a disconnection problem between the electrode part and the connection layer CL may be reduced. In addition, since a propagation path of an electromagnetic wave is long and more energy is absorbed, EMI may be more effectively reduced. The via hole for arranging the connection layer CL may be formed by a machine (e.g., laser cutting) or chemical method as will be described below.

FIG. 15 is a cross-sectional view illustrating a semiconductor package according to the first embodiment.

Referring to FIG. 15, the semiconductor package according to the first embodiment may include the circuit board according to various embodiments described above. Hereinafter, the circuit board will be referred to as a first circuit board.

The semiconductor package includes a first conductive coupling part 410 disposed on an electrode part of the first circuit board. The first conductive coupling part 410 may be disposed on each of the plurality of electrode parts (first electrode parts) of the first circuit board. In particular, the first conductive coupling part 410 may be disposed on a first circuit pattern layer exposed by a cavity in the first circuit board. In the present specification, the conductive coupling part may correspond to a “connection part,” a “conductive part,” and the like for electrical connection.

The first conductive coupling part 410 may have a spherical shape. For example, a cross section of the first conductive coupling part 410 may have a circular shape or a semicircular shape. For example, the cross section of the first conductive coupling part 410 may have a partially or generally round shape. For example, a cross-sectional shape of the first conductive coupling part 410 may be a flat surface on one side surface and a curved surface on the other side surface. The first conductive coupling part 410 may be a solder ball, but the present invention is not limited thereto.

The semiconductor package according to the embodiment may include a chip 420 or a semiconductor element disposed on the first conductive coupling part 410. The chip 420 may be a processor chip. For example, the chip 420 may be an application processor (AP) chip of any one of a central processor (e.g., central processing unit (CPU)), a graphics processor (e.g., graphics processing unit (GPU)), a digital signal processor, an encryption processor, a microprocessor, and a micro-controller.

In this case, a terminal 425 may be included on a lower surface of the chip 420, and the terminal 425 may be electrically connected to the first electrode part (the first circuit pattern layer) of the first circuit board through the first conductive coupling part 410.

Meanwhile, the semiconductor package of the embodiment may be spaced apart from each other on one circuit board by a predetermined distance, and a plurality of chips may be disposed. For example, the chip 420 may include a first chip and a second chip which are spaced apart from each other.

For example, the first circuit board may include a plurality of cavities spaced apart in a width direction or a longitudinal direction. In addition, the first chip and the second chip may be respectively disposed in the plurality of cavities. In this case, at least one terminal of the first chip may be connected to at least one terminal of the second chip. In addition, the first chip and the second chip may be different types of AP chips.

Meanwhile, the first chip and the second chip may be spaced apart from each other on the circuit board by a predetermined distance. Accordingly, electrical reliability may be secured. In addition, loss degradation of signal transmission between the first chip and the second chip or signal transmission for each of the first chip and the second chip may be prevented through a distance between the first chip and the second chip.

Meanwhile, the semiconductor package may include an opening of the outermost insulating layer of the first circuit board or a second conductive coupling part in the opening.

In this case, the second conductive coupling part may be a solder ball, but the present invention is not limited thereto. In an embodiment, the uppermost end of the second conductive coupling part may be located higher than the uppermost end of the chip 420 is located. With this configuration, damage to the circuit board may be prevented. Furthermore, a space for a package substrate or a circuit board, which is additionally disposed in an upper portion, may be easily secured.

In addition, in the embodiment, a protective layer or a third conductive coupling part 440 disposed in the opening of the second insulating layer may be included. The third conductive coupling part 440 may be used to couple the semiconductor package to a main board (or motherboard) of an external device.

Furthermore, the semiconductor package may include a shield layer SL located at an upper portion of the circuit board. The shield layer SL may be disposed at an outer side of the second insulating layer 112.

In addition, the connection layer CL may be electrically connected to the shield layer SL. The shield layer SL may be spaced apart from the second conductive coupling part described above. The shield layer SL may be electrically separated from the second conductive coupling part. Accordingly, electrical reliability of the shield layer SL may be improved.

In addition, the shield layer SL may be disposed on the semiconductor element (or chip), an underfill, and a molding layer mounted in the cavity CV. The shield layer SL may be electrically separated from the semiconductor element (or chip).

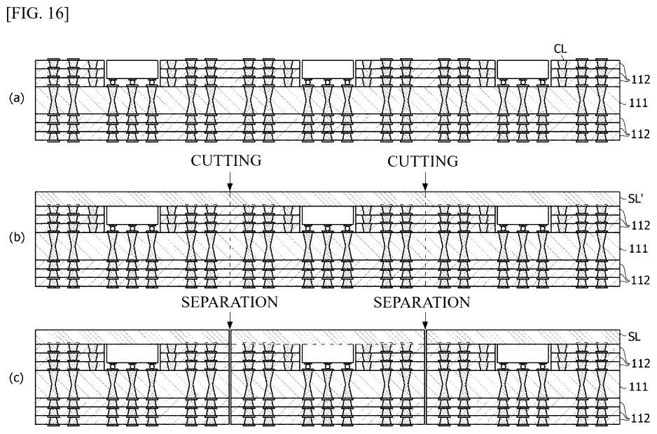

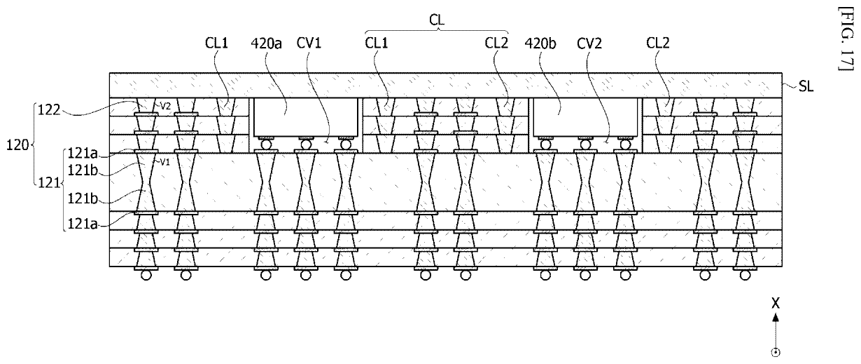

FIG. 16 is a flowchart illustrating a method of manufacturing a semiconductor package according to the first embodiment.

Referring to FIG. 16, a semiconductor element may be mounted in each cavity of a plurality of circuit boards. Thereafter, an under-fill operation may be easily performed after the semiconductor element or the chip is mounted in the cavity CV. Furthermore, molding for the circuit board may be performed (FIG. 16A).

A shield layer SL′ may be formed on the circuit board. The shield layer SL′ may be formed on upper surfaces of the plurality of circuit boards (FIG. 16B). In addition, the shield layer SL′ may be located on side surfaces of the plurality of circuit boards.

In addition, the shield layer SL′ may be formed on the upper surface of the circuit board by various methods. For example, the shield layer SL′ may be formed by sputtering. Accordingly, metal particles may be deposited on an upper portion of the package substrate or on the upper surface of the circuit board. In addition, the metal particles may also be deposited on the side surface of the circuit board.

Furthermore, a plurality of package substrates may be separated from each other. The above-described separation may be performed by various methods. For example, the package substrates may be separated by a physical, a chemical method, or the like.

For example, in each of the plurality of package substrates, the circuit board bonded to the shield layer may be separated into individual circuit boards or package substrates by a saw tooth street or scribe, a saw blade, a cutting tool, a laser, or the like. According to the embodiment, even when the shield layer SL′ is formed on the upper surface of the circuit board or the upper portion of the package substrate, the connection layer of each circuit board and the shield layer SL′ may be electrically connected to each other. Accordingly, even when the shield layer is not formed on the side surface of the circuit board at a deposition rate different from that of the upper surface of the circuit board, a shielding structure for EMI may be formed in the circuit board.

Accordingly, since the connection layer is formed in the circuit board, the shielding layer may not be deposited on the side surface of the circuit board so that there may be no risk of not forming the shield layer on the side surface. Furthermore, it is possible to provide an effect of reducing a process time according to a deposition rate difference. In addition, material costs for forming the shield layer may also be reduced.

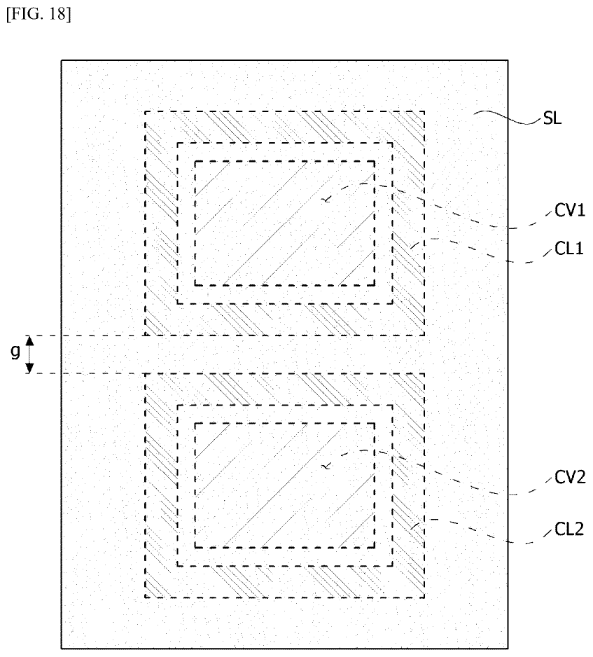

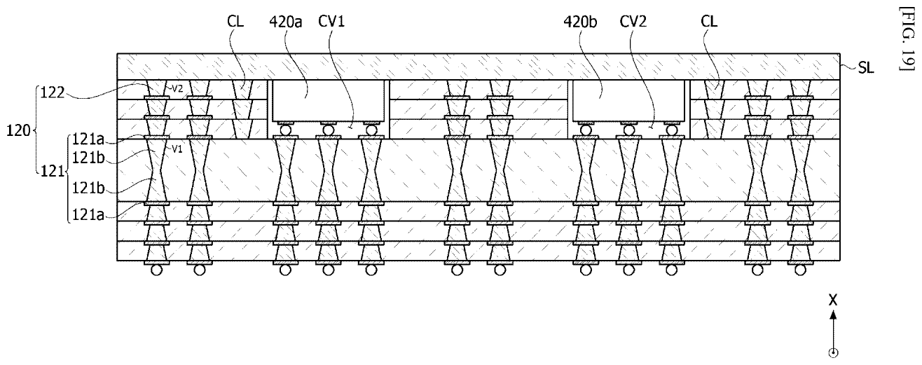

FIG. 17 is a cross-sectional view illustrating a semiconductor package according to the second embodiment, and FIG. 18 is a plan view illustrating a semiconductor package according to the second embodiment.

Referring to FIGS. 17 and 18, the semiconductor package according to the second embodiment may include the circuit board according to various embodiments described above. In addition, the semiconductor package may include all of a shield layer SL, a first conductive coupling part 410, a chip 420, and a third conductive coupling part 440. Furthermore, all of the above-described contents may be applied to contents of the semiconductor package, which will be described below.

Furthermore, the circuit board may include a plurality of cavities CV. For example, the circuit board may include a first cavity CV1 and a second cavity CV2. The first cavity CV1 and the second cavity CV2 may be disposed and spaced apart from each other.

Furthermore, a first chip 420a may be located in the first cavity CV1. In addition, a second chip 420b may be located in the second cavity CV2.

In addition, the circuit board may include a connection layer CL surrounding each cavity. The connection layer CL may be located to correspond to the cavity. The connection layer may include a first connection layer CL1 and a second connection layer CL2. The first connection layer CL1 may be disposed to surround the first cavity CV1. The second connection layer CL2 may be disposed to surround the second cavity CV2.

The first connection layer CL1 and the second connection layer CL2 may be in contact with or spaced apart from each other. With this configuration, electromagnetic shielding for a semiconductor element or a chip disposed in each of the plurality of cavities may be more effectively performed.

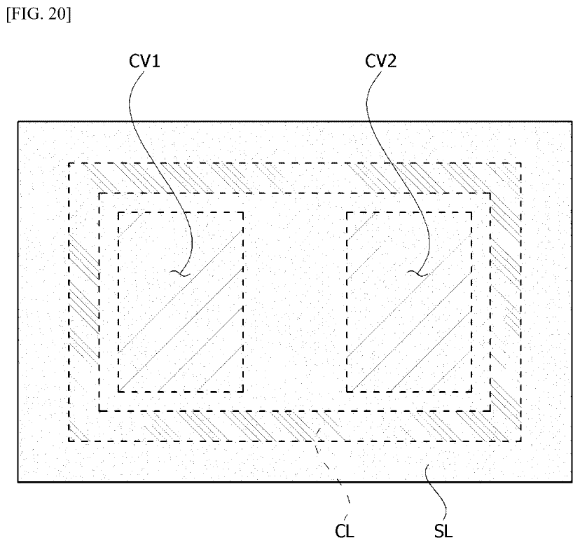

FIG. 19 is a cross-sectional view illustrating a semiconductor package according to the third embodiment, and FIG. 20 is a plan view illustrating a semiconductor package according to the third embodiment.

Referring to FIGS. 19 and 20, the semiconductor package according to the third embodiment may include the circuit board according to various embodiments described above. In addition, the semiconductor package may include all of a shield layer SL, a first conductive coupling part 410, a chip 420, and a third conductive coupling part 440. Furthermore, all of the above-described contents may be applied to contents of the semiconductor package, which will be described below.

Furthermore, the circuit board may include a plurality of cavities CV. For example, the circuit board may include a first cavity CV1 and a second cavity CV2. The first cavity CV1 and the second cavity CV2 may be disposed and spaced apart from each other.

A first chip 420a may be located in the first cavity CV1. In addition, a second chip 420b may be located in the second cavity CV2.

In addition, the circuit board may include a connection layer CL surrounding the cavity. For example, the connection layer CL may surround the plurality of cavities CV. That is, the plurality of cavities and the plurality of semiconductor elements (or chips) may be located inside the connection layer CL. In addition, the connection layer CL may not be present in a region between a plurality of adjacent cavities. Accordingly, the cavity and the connection layer may not overlap each other in a region between the plurality of adjacent cavities. The connection layer CL may be located to correspond to the cavity. Accordingly, a first connection layer CL1 and a second connection layer CL2 of the cavity CV may be in contact with or separated from each other

with only one connection layer CL. With this configuration, electromagnetic shielding for a semiconductor element or a chip disposed in each of the plurality of cavities may be more effectively performed.

Meanwhile, when the circuit substrate having the above-described feature of the present invention is used in information technology devices such as a smartphone, a server computer, and a television (TV), or a home appliance, functions such as signal transmission or power supply may be stably performed. For example, when the circuit substrate having the feature of the present invention performs a semiconductor package function, it is possible to perform a function of safely protecting the semiconductor chip from external moisture or contaminants, and it is possible to solve a problem of a leakage current or electrical short circuit between terminals or an electrical opening of the terminal of supplying power to the semiconductor chip. In addition, when a function of signal transmission is performed, a noise problem may be solved. In this way, the circuit substrate having the above-described feature of the present invention may maintain a stable function of the IT device or the home appliance so that the entire product and the circuit substrate to which the present invention is applied may achieve functional unity or technical interoperability with each other.

When the circuit substrate having the above-described feature of the present invention is used for a transportation device such as a vehicle, it is possible to solve a distortion problem of a signal transmitted to the transportation device or safely protect the semiconductor chip for controlling the transportation device from the outside and solve the leakage current or the electrical short circuit problem between the terminals or the electrical opening problem of the terminal of supplying power to the semiconductor chip so that stability of the transportation device can be further improved. Therefore, the transport device and the circuit substrate to which the present invention is applied may achieve functional unity or technical interoperability with each other.

Features, structures, effects, and the like which are described in the embodiments are included in at least one embodiment and are not necessarily limited to only one embodiment. Furthermore, the features, structures, effects, and the like illustrated in each embodiment may be combined or modified for other embodiments by those skilled in the art to which the embodiments pertain. Therefore, the content related to the combination and the deformation should be construed as being included in the scope of the embodiments.

While the embodiments have been mainly described with reference to the exemplary embodiments, it should be understood that the embodiments are only illustrative and the present invention is not limited to the disclosed embodiments, and various modifications and applications can be devised by those skilled in the art to which the present invention pertains without departing from the essential feature of the present invention. For example, each component specifically shown in the embodiments can be modified and implemented. Further, the differences related to such modifications and applications should be construed as being included in the scope of the embodiments set forth in the appended claims.

1. A circuit board comprising:
a first insulating layer;
a first circuit pattern layer disposed in the first insulating layer;
a second insulating layer disposed on the first insulating layer and the first circuit pattern layer and including a cavity;
a second circuit pattern layer disposed in the second insulating layer; and
a connection layer passing through the second insulating layer and disposed along an edge of the cavity.

2. The circuit board of claim 1, wherein the connection layer overlaps the second circuit pattern layer at an outer side of the cavity in a direction perpendicular to a stack direction.

3. The circuit board of claim 1, wherein the connection layer is disposed between the second circuit pattern layer and the cavity or disposed at an outer side of the second circuit pattern layer.

4. The circuit board of claim 1, wherein the connection layer is electrically connected to the first circuit pattern layer.

5. The circuit board of claim 1, wherein the connection layer is electrically connected to the second circuit pattern layer.

6. The circuit board of claim 1, wherein the connection layer surrounds the cavity in a form of an open loop or a closed loop.

7. The circuit board of claim 1, wherein:
the connection layer includes a plurality of first sub-connection layers and a plurality of second sub-connection layers, which are adjacent to each other; and
the first sub-connection layer and the second sub-connection layer are disposed and spaced apart from each other.

8. The circuit board of claim 1, further comprising a first extension extending in a direction perpendicular to a stack direction and configured to connect the connection layer to the second circuit pattern layer.

9. The circuit board of claim 8, wherein the first extension is disposed in the second insulating layer.

10. The circuit board of claim 1, further comprising a second extension extending in a stack direction and configured to connect the connection layer to the first circuit pattern layer.

11. The circuit board of claim 10, wherein the second extension is disposed in the first insulating layer.

12. The circuit board of claim 1, wherein the cavity includes a first cavity and a second cavity spaced apart from the first cavity.

13. The circuit board of claim 12, wherein the connection layer includes a first connection layer surrounding the first cavity and a second connection layer surrounding the second cavity.

14. The circuit board of claim 13, wherein the first connection layer and the second connection layer are in contact with or spaced apart from each other.

15. A package substrate comprising:
a circuit board;
a semiconductor element connected to the circuit board; and
a connection part configured to connect the semiconductor element to the circuit board,
wherein the circuit board includes:
a first insulating layer;
a first circuit pattern layer disposed in the first insulating layer;
a second insulating layer disposed on the first insulating layer and the first circuit pattern layer and including a cavity;
a second circuit pattern layer disposed in the second insulating layer; and
a connection layer passing through the second insulating layer and disposed along an edge of the cavity,
the package substrate further includes a shield layer disposed at an outer side of the second insulating layer, and
the connection layer is electrically connected to the shield layer.

16. The package substrate of claim 15, wherein the connection layer overlaps the second circuit pattern layer at an outer side of the cavity in a direction perpendicular to a stack direction.

17. The package substrate of claim 15, wherein the connection layer is disposed between the second circuit pattern layer and the cavity or disposed at an outer side of the second circuit pattern layer.

18. The package substrate of claim 15, wherein the connection layer is electrically connected to the first circuit pattern layer.

19. The package substrate of claim 15, wherein the connection layer is electrically connected to the second circuit pattern layer.

20. The package substrate of claim 15, wherein the connection layer surrounds the cavity in a form of an open loop or a closed loop.
